(19) United States
(12) Patent Application Publication
(10) Pub. No.: US 2025/0046757 A1
(43) Pub. Date: Feb. 6, 2025

(54) SEMICONDUCTOR PACKAGE INCLUDING CONDUCTIVE POSTS AND A HEAT SPREADER AND A METHOD OF FABRICATING THE SAME

(71) Applicant: SAMSUNG ELECTRONICS CO., LTD., SUWON-SI (KR)

(72) Inventors: HYUNSOO CHUNG, Suwon-si (KR); KWANG-SOO KIM, Suwon-si (KR); JAESIC LEE, Suwon-si (KR)

(21) Appl. No.: 18/589,650

(22) Filed: Feb. 28, 2024

(30) Foreign Application Priority Data
Aug. 2, 2023 (KR) 10-2023-0101135

(51) Int. Cl. H01L 25/065; H01L 23/00; H01L 23/373; H01L 23/48; H10B 80/00

(52) U.S. Cl. CPC H01L 25/0657; H01L 23/3738; H01L 23/481; H01L 24/08; H01L 24/16; H01L 25/0652; H10B 80/00; H01L 24/96; H01L 24/97; H01L 2224/08059; H01L 2224/0807; H01L 2224/08145; H01L 2224/08225; H01L 2224/16227; H01L 2224/96; H01L 2224/97; H01L 2225/06544; H01L 2225/06548; H01L 2225/06589; H01L 2924/1431

(57) ABSTRACT

Disclosed are semiconductor packages and their fabrication methods. The semiconductor package comprises a base die that includes first dummy pads on an edge at a top surface of the base die; a plurality of memory dies on the base die; a plurality of conductive posts spaced apart from the memory dies and on the edge of the base die; a mold layer that covers the base die, the memory dies, and the conductive posts; and a heat spreader that includes second dummy pads on an edge at a bottom surface of the heat spreader and third dummy pads on a central portion of the bottom surface of the heat spreader, wherein the heat spreader is disposed on the memory dies and the mold layer. The first dummy pads are correspondingly connected to the second dummy pads through the conductive posts and the second dummy pads are in contact with the conductive posts.

### CROSS-REFERENCE TO RELATED APPLICATION

This U.S. nonprovisional application claims priority under 35 U.S.C. § 119 to Korean Patent Application No. 10-2023-0101135 filed on Aug. 2, 2023 in the Korean Intellectual Property Office, the disclosure of which is incorporated by reference herein in its entirety.

### 1. TECHNICAL FIELD

The present inventive concepts relate to a semiconductor package and a method of fabricating the same, and more particularly, to a stacked semiconductor package including conductive posts and a heat spreader and a method of fabricating the same.

### 2. DISCUSSION OF THE RELATED ART

A semiconductor package implements an integrated circuit chip for use in electronic products. Typically, a semiconductor package is configured such that a semiconductor chip is mounted on a printed circuit board (PCB), and semiconductor chip is electrically connected to the printed circuit board using bonding wires or bumps.

### SUMMARY

Some embodiments of inventive concepts provide a semiconductor package with increased reliability and improved heat dissipation performance.

Some embodiments of the present inventive concepts provide a method of fabricating a semiconductor package, which method increases a yield.

According to some embodiments of the present inventive concepts, a semiconductor package may comprise: a base die that includes first dummy pads on an edge at a top surface of the base die; a plurality of memory dies on the base die; a plurality of conductive posts spaced apart from the memory dies and on the edge of the base die; a mold layer that covers the base die, the memory dies, and the conductive posts; and a heat spreader that includes second dummy pads on an edge at a bottom surface of the heat spreader and third dummy pads on a central portion of the bottom surface of the heat spreader, wherein the heat spreader is disposed on the memory dies and the mold layer. The first dummy pads are correspondingly connected to the second dummy pads through the conductive posts and the second dummy pads are in contact with the conductive posts.

According to some embodiments of the present inventive concepts, a semiconductor package may comprise: a base die; a plurality of memory dies on the base die; a plurality of conductive posts spaced apart from the memory dies and disposed on an edge of the base die; a mold layer covers the base die, the memory dies, and the conductive posts; and a heat spreader on the memory dies and the mold layer. The base die includes a first substrate; a first through via that penetrates the first substrate and is disposed on a central portion of the base die; a plurality of upper conductive pads on a top surface of the base die and connected to the first through via; a plurality of first dummy pads on the edge at the top surface of the base die; and a plurality of lower conductive pads on a bottom surface of the base die. The memory dies include first, second, third and fourth memory dies that are stacked. Each of the first to fourth memory dies includes: a second substrate; a second through via that penetrates the second substrate and resides on a central portion of the memory die; a plurality of upper chip pads on a top surface of the memory die and connected to the second through via; and a plurality of lower chip pads on a bottom surface of the memory die and connected to the second through via. The heat spreader includes: a plurality of second dummy pads on an edge at a bottom surface of the heat spreader; and a plurality of third dummy pads on a central portion of the bottom surface of the heat spreader. The conductive posts are spaced apart from each other and surround the memory dies. A diameter of at least one of the conductive post is greater than a diameter of each of the first and second through vias. The heat spreader and the base die have the same first width, the first to fourth memory dies have the same second width, wherein the first width is greater than the second width. The heat spreader includes silicon.

According to some embodiments of the present inventive concepts, a semiconductor package may comprise: a package substrate; an interposer substrate on the package substrate; a first semiconductor chip on the interposer substrate; and a second semiconductor chip on the interposer substrate. The second semiconductor chip includes: a base die that includes first dummy pads on an edge at a top surface of the base die; a plurality of memory dies on the base die; a plurality of conductive posts spaced apart from the memory dies and on the edge of the base die; a mold layer that covers the base die, the memory dies, and the conductive posts; and a dummy die that includes second dummy pads on an edge at a bottom surface of the dummy die and third dummy pads on a central portion of the bottom surface of the dummy die, the dummy die being disposed on the memory dies and the mold layer. The dummy die and the base die have the same first width.

According to some embodiments of the present inventive concepts, a method of fabricating a semiconductor package may comprise: providing a base die wafer that includes a first through via; forming a plurality of lower conductive pads and a plurality of external connection members bonded to the lower conductive pads, the lower conductive pads being on a bottom surface of the base die wafer; bonding a carrier substrate through an adhesive member to the bottom surface of the base die wafer; forming a plurality of upper conductive pads and a plurality of first dummy pads, the upper conductive pads being connected to the first through via and on a top surface of the base die wafer, and the first dummy pads being on an edge of the base die wafer; forming on the edge of the base die wafer a plurality of conductive posts in contact with the first dummy pads; providing a plurality of memory dies that includes a second through via; forming a plurality of upper chip pads on top surfaces of the memory dies and a plurality of lower chip pads on bottom surfaces of the memory dies, the upper chip pad and the lower chip pad being connected to the second through via; using a hybrid copper bonding to bond the memory dies to the base die wafer so that the upper conductive pads contact the lower chip pads; forming a molding member that covers a top surface of the base die wafer, lateral surfaces of the memory dies, and the conductive posts; performing a planarization process to remove at least portions of the conductive posts and at least a portion of the molding member to expose top surfaces of the conductive posts, the upper chip pads, the memory dies, and the molding member; preparing a dummy die wafer that includes second and third dummy pads on a bottom surface of the dummy die wafer; using a hybrid copper bonding to bond the dummy die wafer to the memory dies, the molding member, and the conductive posts so that the second dummy pads contact the conductive posts and the third dummy pads contact the upper chip pads; and separating the carrier substrate and the adhesive member from the base die wafer.

### BRIEF DESCRIPTION OF THE DRAWINGS

FIG. 1 is a cross-sectional view showing a semiconductor package according to some embodiments of the present inventive concepts.

FIGS. 2A and 2B are enlarged views showing section P1 of FIG. 1.

FIGS. 2C and 2D are enlarged views showing section P2 of FIG. 1.

FIG. 2E is an enlarged view showing section P3 of FIG. 1.

FIG. 3 is a plan view taken along line A-A′ of the semiconductor package depicted in FIG. 1.

FIGS. 4A, 4B, 4C, 4D, 4E, 4F, 4G, and 4H are cross-sectional views showing a method of fabricating a semiconductor package depicted in FIG. 1.

FIG. 5 is a cross-sectional view showing a semiconductor package according to some embodiments of the present inventive concepts.

FIGS. 6A, 6B, 6C, 6D, 6E, 6F, and 6G are cross-sectional views showing a method of fabricating the semiconductor package depicted in FIG. 5.

FIG. 7 is a cross-sectional view showing a semiconductor package according to some embodiments of the present inventive concepts.

FIG. 8 is a cross-sectional view showing a semiconductor package according to some embodiments of the present inventive concepts.

### DETAILED DESCRIPTION OF THE EMBODIMENTS

Some embodiments of the present inventive concepts will now be described in detail with reference to the accompanying drawings to aid in clearly explaining the present inventive concepts.

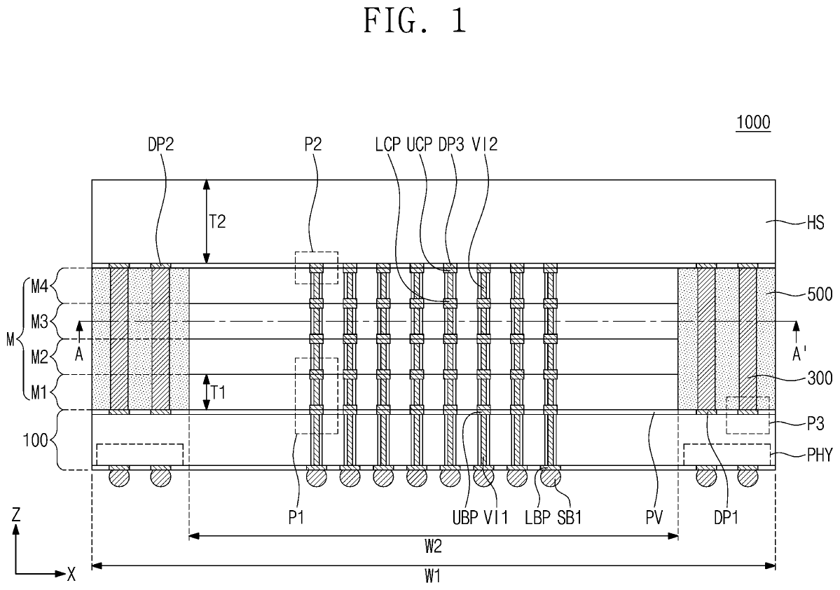

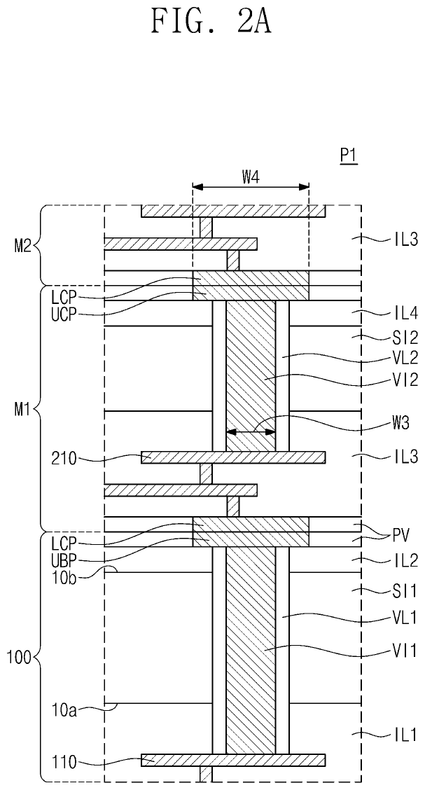

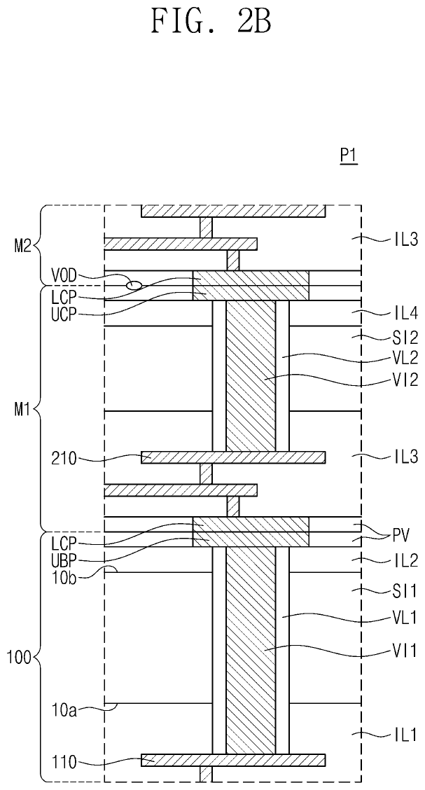

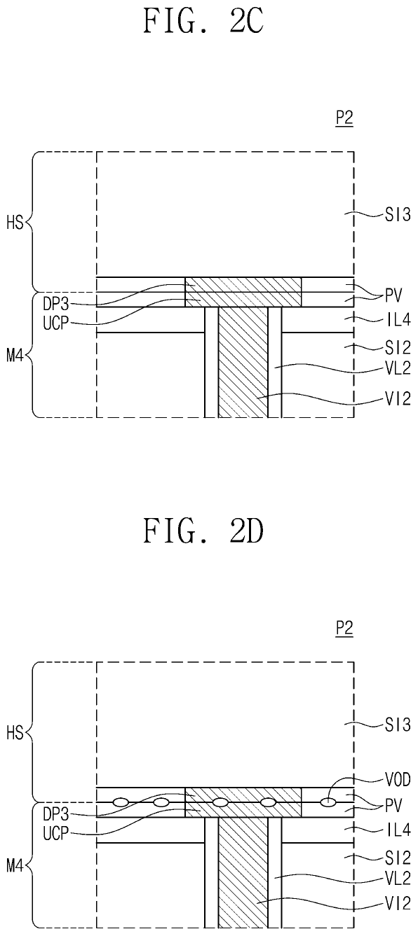

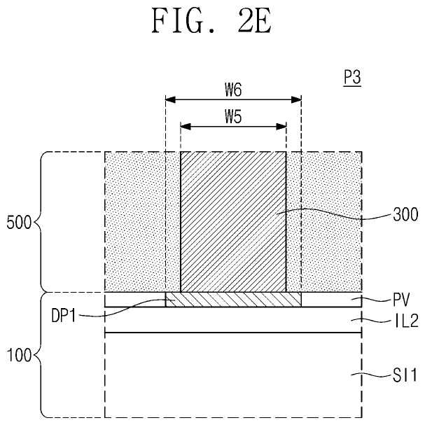

FIG. 1 is a cross-sectional view showing a semiconductor package according to some embodiments of the present inventive concepts. FIGS. 2A and 2B are enlarged views showing section P1 of FIG. 1. FIGS. 2C and 2D illustrate enlarged views showing section P2 of FIG. 1. FIG. 2E illustrates an enlarged view showing section P3 of FIG. 1.

Referring to FIG. 1, a semiconductor package 1000 according to some embodiments of the present inventive concepts may include a base die 100, memory dies M, conductive posts 300, a mold layer 500, and a heat spreader HS. The term “die” may be called a chip. The heat spreader HS may be called a dummy die or a stiffener. In this description, the term “dummy die” may mean a semiconductor die including no integrated circuits therein. The base die 100 and the heat spreader HS may have the same first width W1 in a first direction X.

The base die 100 may be, for example, a logic circuit chip. The base die 100 may serve as an interface circuit between the memory dies M and an external controller. The base die 100 may receive commands, data, and signals transmitted from the external controller, and may transfer the received commands, data, and signals to the memory dies M.

The memory dies M may include first to fourth memory dies M1 to M4 that are sequentially stacked. The first to fourth memory dies M1 to M4 may be the same memory chip. The memory dies M may be, for example, dynamic random access memory (DRAM), NAND Flash, static random access memory (SRAM), magnetic random access memory (MRAM), phase change random access memory (PRAM), or resistive random access memory (RRAM). The first to fourth memory dies M1 to M4 may have the same second width W2 in the first direction X. The first width W1 of the base die 100 and the heat spreader HS may be greater than the second width W2 of the memory dies M. The first to fourth memory dies M1 to M4 may have the same first thickness T1 in a second direction Z. As the memory dies M have the same size, it may be possible to carry out effective production and management of the semiconductor package 1000.

Referring to FIGS. 1 and 2A, the base die 100 may include a first substrate SI1 and first and second interlayer dielectric layers IL1 and IL2. Each of the first, second, third, and fourth memory dies M1, M2, M3, and M4 may include a second substrate SI2 and third and fourth interlayer dielectric layers IL3 and IL4. Each of the first and second substrates SI1 and SI2 may have a front surface 10a and a rear surface 10b that are disposed on opposite sides to each other. The first and second substrates SI1 and SI2 may be a wafer-level semiconductor substrate formed of a semiconductor including silicon (Si). For example, the first and second substrates SI1 and SI2 may each be a monocrystalline silicon substrate or a silicon-on-insulator (SOI) substrate. The first substrate SI1 may be provided on its front surface 10a with transistors and first internal lines 110. The second substrate SI2 may be provided on its front surface 10a with transistors and second internal lines 210. The internal lines 110 and 210 may be a single-layered or multi-layered structure formed of at least one selected from copper, aluminum, tungsten, titanium, titanium nitride, tantalum, tantalum nitride, ruthenium, and/or iridium. The first and third interlayer dielectric layers IL1 and IL3 may cover the front surfaces 10a of the first and second substrates SI1 and SI2, respectively. The second and fourth interlayer dielectric layers IL2 and IL4 may cover the rear surfaces 10b of the first and second substrates SI1 and SI2, respectively. The interlayer dielectric layers IL1 to IL4 may be a single-layered or multi-layered structure formed of at least one selected from silicon oxide, silicon nitride, silicon oxynitride, and/or porous dielectrics. The interlayer dielectric layers IL1 to IL4 may be correspondingly covered with passivation layers PV. The passivation layers PV may include at least one selected from silicon oxide, silicon nitride, and/or silicon carbonitride.

The base die 100 may include a first through via VI1. Each of the first, second, third, and fourth memory dies M1, M2, M3, and M4 may include a second through via VI2. The first and second through vias VI1 and VI2 may vertically penetrate the first substrate SI1 of the base die 100 and the second substrates SI2 of the first, second, third, and fourth memory dies M1, M2, M3, and M4 to reside central portions of corresponding dies 100, M1, M2, M3, and M4. The internal lines 110 and 210 may be connected to the first and second through vias VI1 and VI2 that penetrate corresponding dies 100, M1, M2, M3, and M4. For example, top surfaces of the internal lines 110 and 210 may contact the first and second through vias VI1 and VI2. Through dielectric layers VL1 and VL2 may be interposed between the first and second through vias VI1 and VI2 and the first and second substrates SI1 and SI2. For example, the through dielectric layers VL1 and VL2 may at least partially surround the corresponding the first and second through vias VI1 and VI2. The first and second through vias VI1 and VI2 may include metal such as copper, aluminum, or tungsten. The through dielectric layers VL1 and VL2 may be a single-layered or multi-layered structure formed of at least one selected from silicon oxide, silicon nitride, and/or silicon oxynitride. The through dielectric layers VL1 and VL2 may include an air gap.

The base die 100 may be provided with upper conductive pads UBP on a top surface thereof. The upper conductive pads UBP may be connected to corresponding first through vias VI1. The base die 100 may be provided with lower conductive pads LBP on a bottom surface thereof. First dummy pads DP1 may be disposed on top surface of the base die 100, adjacent to the lateral side of the base die 100. In this description, the term “dummy pad” may mean a conductive pad to which no electrical signal or no voltage is applied.

Each of the first to fourth memory dies M1 to M4 may be provided with upper chip pads UCP on a top surface thereof. Each of the first to fourth memory dies M1 to M4 may be provided with lower chip pads LCP on a bottom surface thereof. The upper and lower chip pads UCP and LCP may be correspondingly connected to the second through vias VI2. For example, the second through vias VI2 may be disposed between the upper chip pads UCP and the lower chip pads LCP. Second dummy pads DP2 may be disposed at bottom surface of the heat spreader HS, adjacent to the lateral side of the heat spreader HS. Third dummy pads DP3 may be disposed at bottom surface of the heat spreader HS, near a central portion of the heat spreader HS. The first and second dummy pads DP1 and DP2 may be correspondingly in contact with conductive posts 300. For example, the first dummy pads DP1 may be correspondingly connected to the second dummy pads DP2 through the conductive posts 300. The upper conductive pads UBP, the lower conductive pads LBP, the upper chip pads UCP, the lower chip pads LCP, and the first to third dummy pads DP1 to DP3 may include at least one metal selected from copper (Cu), gold (Au), nickel (Ni), silver (Ag), tungsten (W), and/or aluminum (Al). First external connection members SB1 may be correspondingly bonded to the lower conductive pads LBP. The first external connection members SB1 may include at least one selected from copper bumps, copper pillars, and/or solder balls.

The conductive posts 300 may be disposed on an edge of the base die 100. The conductive posts 300 may be spaced apart from the memory dies M. The conductive posts 300 may include a material such as copper (Cu). The base die 100 may include high-power density regions PHY to which a relatively large power is applied. The conductive posts 300 may be disposed on the high-power density regions PHY. The high-power density regions PHY may be areas where integrated circuits (transistors and wiring lines) are disposed to which a high voltage is applied. For example, the high-power density regions PHY may include integrated circuits (transistors and wiring lines) to which a high voltage is applied. During an operation of the semiconductor package 1000, a large amount of heat may be generated from the high-power density regions PHY. As the conductive posts 300 are disposed above the high-power density regions PHY, it may be possible to effectively discharge heat generated from the base die 100 and to reduce heat transferred to the memory dies M. Therefore, the semiconductor package 1000 may be prevented from malfunction and may improve in reliability and heat dissipation performance.

The mold layer 500 may at least partially cover the top surface of the base die 100, lateral surfaces of the memory dies M, and the conductive posts 300. The mold layer 500 may include a dielectric resin, such as an epoxy molding compound (EMC). The mold layer 500 may further include fillers, and the fillers may be dispersed in the dielectric resin. The fillers may include, for example, silicon oxide (SiO₂).

Referring to FIGS. 1 and 2C, the heat spreader HS may be disposed on the memory dies M, the conductive posts 300, and the mold layer 500. The heat spreader HS may have a second thickness T2 in the second direction Z, and the second thickness T2 of the heat spreader HS may be greater than the first thickness T1 of the memory dies M. The heat spreader HS may include a third substrate SI3. The third substrate SI3 may be a monocrystalline silicon substrate or a silicon-on-insulator (SOI) substrate. In some embodiments, the third substrate SI3 may be a power semiconductor substrate including silicon carbide (SiC). The second dummy pads DP2 may be disposed on the edge at the bottom surface of the heat spreader HS, and the third dummy pads DP3 may be disposed on the central portion of the bottom surface of the heat spreader HS. The passivation layer PV may at least partially cover a bottom surface of the third substrate SI3 and lateral sides of the second and third dummy pads DP2 and DP3.

Referring to FIG. 2A, the upper conductive pads UBP of the base die 100 may be in direct contact with the lower chip pads LCP of the first memory die M1. The passivation layer PV of the base die 100 may be in direct contact with the passivation layer PV of the first memory die M1. The upper conductive pads UBP and the lower chip pads LCP may be formed of the same material. The upper conductive pad UBP and the lower chip pad LCP that are in contact with each other may merge into a single unitary object. Thus, no interface may be present between the upper conductive pad UBP and the lower chip pad LCP that are in contact with each other.

The upper chip pads UCP of the first memory die M1 may be in direct contact with the lower chip pads LCP of the second memory die M2. Referring back to FIGS. 1 and 2A, the upper and lower chip pads UCP and LCP of the first to fourth memory dies M1 to M4 may be correspondingly in direct contact with each other. The passivation layers PV of the first to fourth memory dies M1 to M4 may be in direct contact with each other. The upper and lower chip pads UCP and LCP may be formed of the same material. One of the upper chip pads UCP and one of the lower chip pads LCP in contact may merge into a single unitary object. Thus, no interface may be present between one of the upper chip pads UCP and one of the lower chip pads LCP in contact.

Referring to FIG. 2C, the upper chip pads UCP of the fourth memory die M4 may be in direct contact with the third dummy pads DP3 of the heat spreader HS. The passivation layer PV of the fourth memory die M4 may be in direct contact with the passivation layer PV of the heat spreader HS. The upper chip pads UCP of the fourth memory die M4 and the third dummy pads DP3 of the heat spreader HS may be formed of the same material. One of the upper chip pads UCP of the fourth memory die M4 and one of the third dummy pads DP3 of the heat spreader HS in contact may merge into a single unitary object. Thus, no interface may be present between one of the upper chip pads UCO and one of the third dummy pads DP3 in contact.

Referring to FIGS. 2B and 2D, voids VOD may be present between the heat spreader HS and the fourth memory die M4 positioned at top of the memory dies M. In addition, voids VOD may be disposed between the first to fourth memory dies M1 to M4. A density of the voids VOD between the fourth memory die M4 and the heat spreader HS may be greater than a density of the voids VOD between ones of the first to four memory dies M1 to M4.

As shown in FIG. 2A, a diameter of each of the first and second through vias VI1 and VI2 may have a third width W3. Each of the upper and lower chip pads UCP and LCP of the first to fourth memory dies M1 to M4 may have a fourth width W4. As shown in FIG. 2E, a diameter of each of the conductive posts 300 may have a fifth width W5, and the fifth width W5 may be greater than the third width W3. The first dummy pads DP1 in contact with the conductive posts 300 may each have a sixth width W6, and the sixth width W6 may be greater than the fourth width W4. The second and third dummy pads DP2 and DP3 may have the same width as that of the first dummy pads DP1.

The present embodiment discloses a structure where one logic circuit chip and four memory dies M are stacked, but the number of the logic circuit chip and the number of the memory dies M may vary without being necessarily limited thereto. For example, eight or more memory dies may be stacked. The semiconductor package 1000 may have a high bandwidth memory (HBM) chip structure.

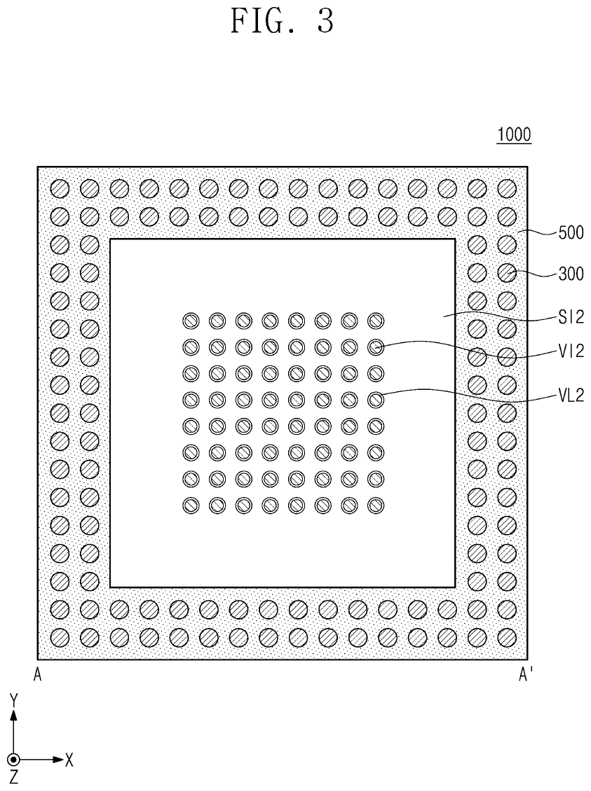

FIG. 3 illustrates a plan view taken along line A-A′ of the semiconductor package depicted in FIG. 1. FIG. 3 may correspond to a plan view of the semiconductor package depicted in FIG. 1.

Referring to FIGS. 1 and 3, the conductive posts 300 may be spaced apart from the memory dies M and from each other. The conductive posts 300 may constitute a plurality of rows and surround all sides of the memory dies M. Thus, the semiconductor package 1000 may be provided which can effectively disperse heat and to have improved heat dissipation performance. The present embodiment shows that the conductive posts 300 are illustrated to be circular shapes when viewed in plan, but the present inventive concepts are not necessarily limited thereto and the conductive posts 300 may be circular shapes, oval shapes, tetragonal shapes, or any other suitable shapes when viewed in plan.

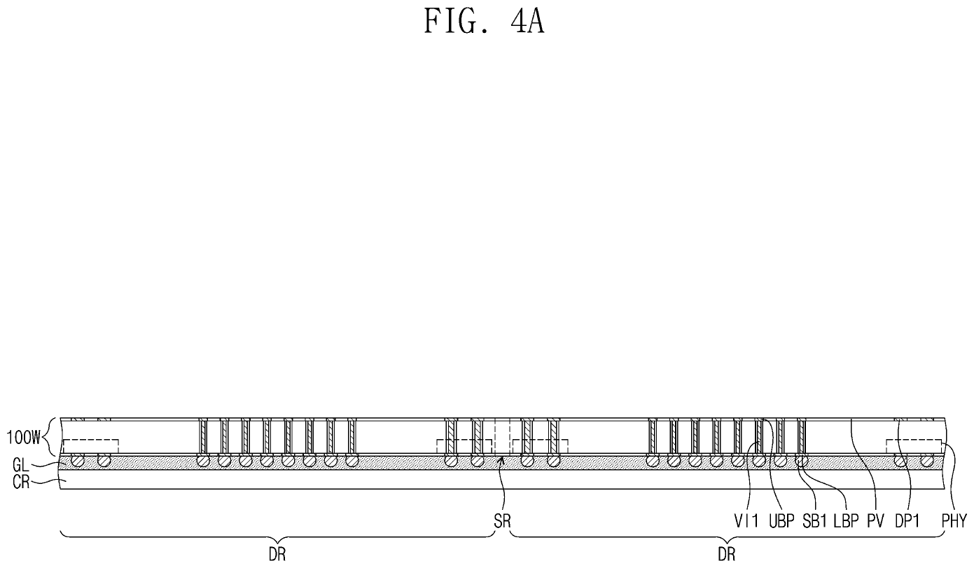

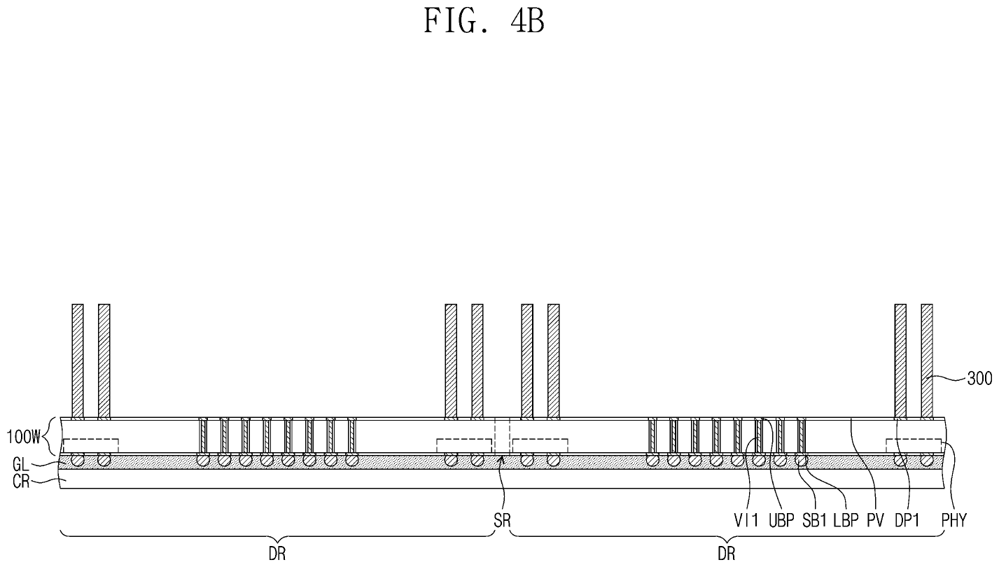

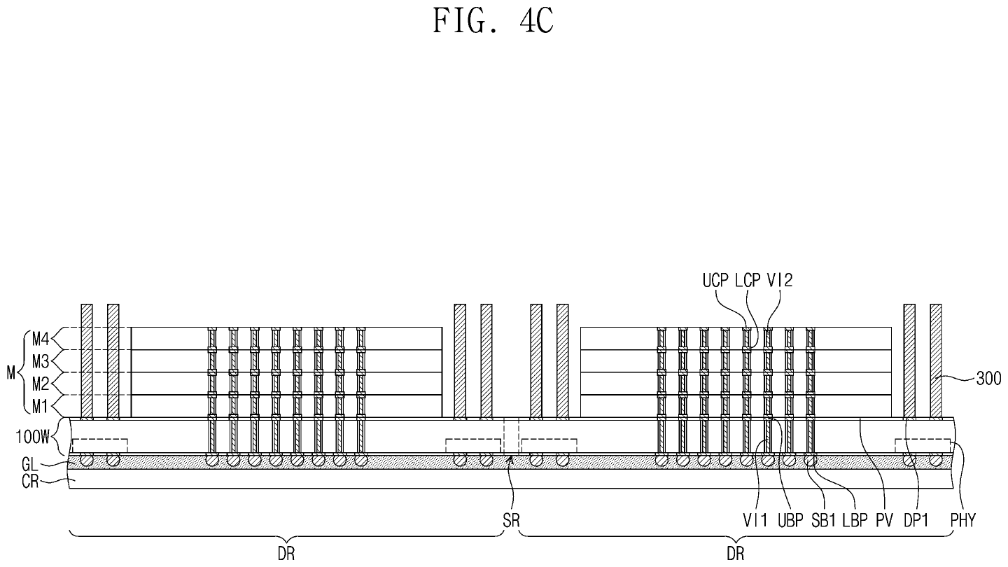

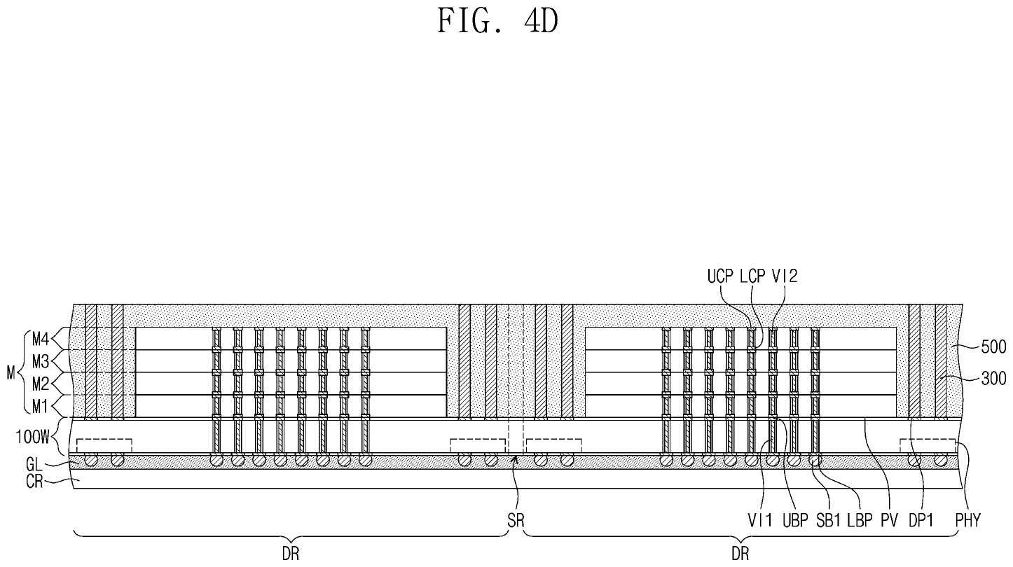

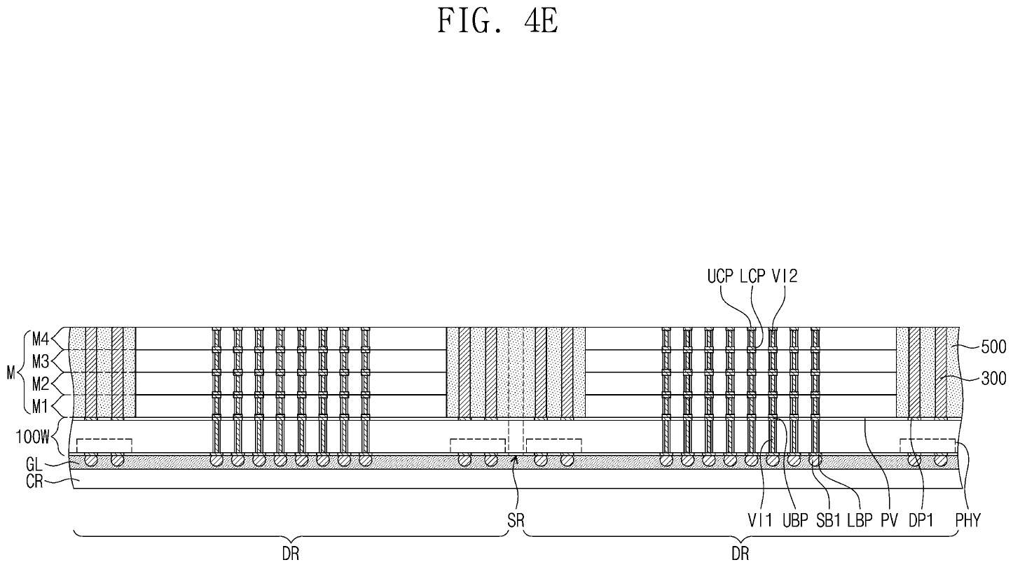

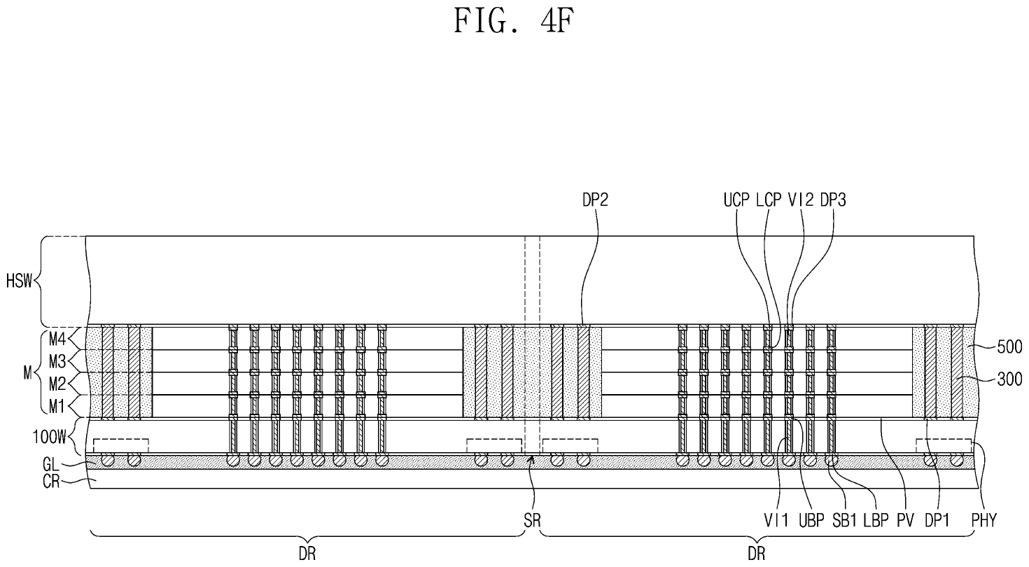

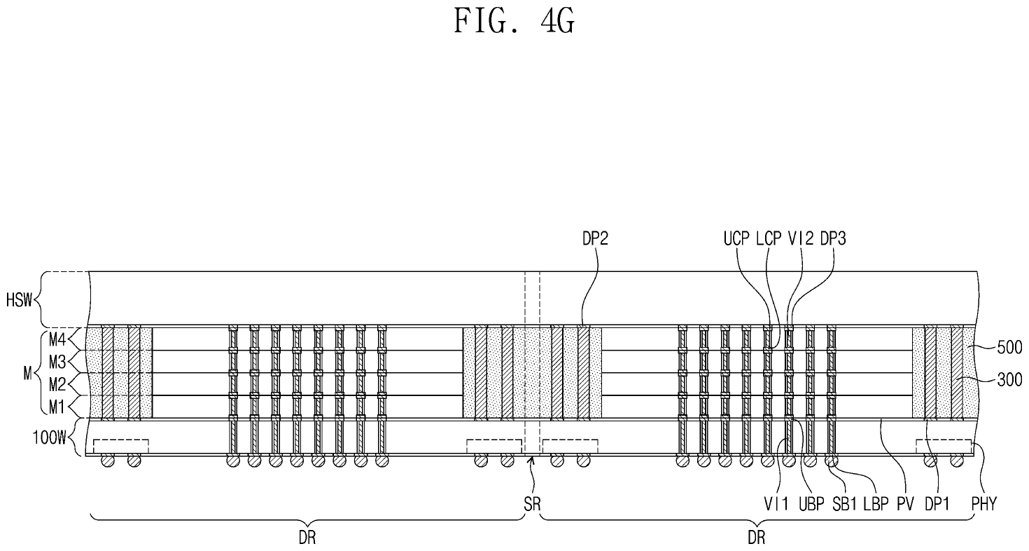

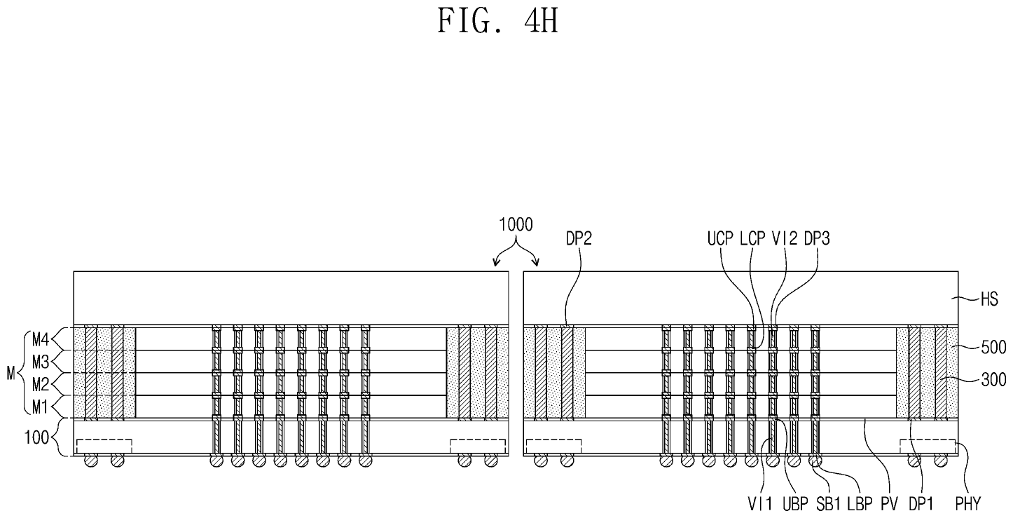

FIGS. 4A to 4H illustrate cross-sectional views showing a method of fabricating the semiconductor package depicted in FIG. 1. A duplicate description will be omitted below.

Referring to FIGS. 2A and 4A, a base die wafer 100W may be prepared. The base die wafer 100W may have a plurality of chip regions DR and a separation region SR between the chip regions DR. The chip regions DR of the base die wafer 100W may each have a structure of the base die 100 discussed with reference to FIGS. 1 to 2B. The separation region SR may be a scribe lane region. The base die wafer 100W may include a first substrate SI1. Transistors and first internal lines 110 may be formed on a front surface 10a of the first substrate SI1, and a portion of the first interlayer dielectric layer IL1 may be formed to cover the transistors and the first internal lines 110. A portion of the first interlayer dielectric layer IL1 and the first substrate SI1 may be etched to form a first through hole, and a first through via VI1 and a first through dielectric layer VL1 may be formed in the first through hole. The first internal lines 110 may be formed contacting the first through via VI1, and the first interlayer dielectric layer IL1 may be formed. Lower conductive pads LBP and a passivation layer PV may be formed on the first interlayer dielectric layer IL1. First external connection members SB1 may be provided which are connected to the lower conductive pads LBP. The base die wafer 100W may be bonded to a carrier substrate CR through a carrier adhesive layer GL so that the first external connection members SB1 to faces down. The carrier adhesive layer GL may include one or more of an adhesive resin, a thermosetting resin, a thermoplastic resin, and/or a photo-curable resin.

A grinding or etch-back process may be performed on a rear surface 10b of the first substrate SI1, such that a portion of the first substrate SI1 may be removed to expose the first through dielectric layer VL1. A top surface of the first substrate SI1 may become lower than an end of the first through via VI1. For example, a grinding process may reduce a thickness of the first substrate SI1. The first through via VI1 may vertically protrude from the top surface of the first substrate SI1. A second interlayer dielectric layer IL2 may be formed on the top surface of the first substrate SI1. A chemical mechanical polishing (CMP) or etch-back process may be performed to remove at least a portion of the second interlayer dielectric layer IL2 and a portion of the first through dielectric layer VL1 to expose the first through via VI1. Upper conductive pads UBP and first dummy pads DP1 may be formed on the second interlayer dielectric layer IL2, and a passivation layer PV may be formed to cover the upper conductive pads UBP and the first dummy pads DP1.

Referring to FIG. 4B, conductive posts 300 may be formed on an edge of the base die wafer 100W. The conductive posts 300 may be in direct contact with the first dummy pads DP1 and may be spaced apart from the upper conductive pads UBP.

Referring to FIGS. 2A and 4C, memory dies M may be prepared. The memory dies M may include first to fourth memory dies M1 to M4. Each of the first to fourth memory dies M1 to M4 may be provided by performing the method discussed in FIG. 4A to form a second substrate SI2, transistors, second internal lines 210, third and fourth interlayer dielectric layers IL3 and IL4, a second through via VI2, a second through dielectric layer VL2, upper chip pads UCP, lower chip pads LCP, and passivation layers PV. Afterwards, a sawing process may be performed to allow the first to fourth memory dies M1 to M4 to be the same size. The first to fourth memory dies M1 to M4 may have the same thickness. The stacking of the first to fourth memory dies M1 to M4 having the same size may facilitate easy management of the memory dies M and increase productivity of a semiconductor package (see 1000 of FIG. 4H).

The first to fourth memory dies M1 to M4 may be stacked on the chip regions DR of the base die wafer 100W. The memory dies M may be stacked to a height less than that of the conductive posts 300. The memory dies M may be bonded by direct bonding or hybrid Cu bonding. The second memory die M2 may allow an active surface of the second memory die M2 to face the first memory die M1. The second memory die M2 may be disposed on the first memory die M1 to allow the third interlayer dielectric layer IL3 to contact the second substrate SI2 and also to allow the lower chip pads LCP of the second memory die M2 to contact the upper chip pads UCP of the first memory die M1. Then a thermocompression process may be performed to directly bond the second memory die M2 to the first memory die M1. The first memory die M1 and the second memory die M2 may be directly bonded through the upper chip pads UCP of the first die M1 and the lower chip pads LCP of the second die M2, and may have an interface formed by their contact with each other. Referring to FIG. 2A, an inorganic dielectric layer such as a silicon oxide layer may be formed between the passivation layer PV of the first memory die M1 and the passivation layer PV of the second memory die M2. The method discussed above may be used to bond the second memory die M2 to the first memory die M1, the third memory die M3 onto the second memory die M2, and the fourth memory die M4 to the third memory die M3.

In some embodiments, a thermocompression process may be performed in a state where the first to fourth memory dies M1 to M4 are stacked, such that the first to fourth memory dies M1 to M4 may be bonded to each other simultaneously. As shown in FIG. 2B, thermocompression process performed on the first to fourth memory dies M1 to M4 of same size significantly suppresses the formation of the voids VOD between the first to fourth memory dies M1 to M4.

The thermocompression process may bond the sequentially stacked memory dies M to the base die wafer 100W. In this case, a direct bonding process or a hybrid Cu bonding process may be performed on the first memory die M1 and the base die wafer 100W. The first memory die M1 may be disposed to allow an active surface of the first memory die M1 to face the base die wafer 100W. The first memory die M1 may be positioned on the base die wafer 100W to allow the third interlayer dielectric layer IL3 to contact the first substrate SI1 and also to allow the lower chip pads LCP of the first memory die M1 to contact the upper conductive pads UBP of the base die wafer 100W. Then a thermocompression process may be performed to directly bond the first memory die M1 to the base die wafer 100W. The base die wafer 100W and the first memory die M1 may be directly bonded through the upper conductive pads UBP of the base die wafer 100W and the lower chip pads LCP of the first memory die M1, and may have an interface formed by their contact with each other. Referring to FIG. 2A, an inorganic dielectric layer such as a silicon oxide layer may be formed between the passivation layer PV of the base die wafer 100W (or a base die 100) and the passivation layer PV of the first memory die M1.

Referring to FIG. 4D, a thermocompression process may be performed to bond the memory dies M to the base die wafer 100W, and then a mold process may be performed to form a mold layer 500 that at least partially covers a top surface of the base die wafer 100W, lateral surfaces of the memory dies M, and the conductive posts 300.

Referring to FIG. 4E, a chemical mechanical polishing (CMP) or etch-back process may be performed to remove at least portions of the conductive posts 300 and at least a portion of the mold layer 500, exposing top surfaces of the conductive posts 300, the fourth memory die M4, the upper chip pads UCP of the fourth memory die M4, and the mold layer 500.

Referring to FIGS. 2C and 4F, a thermocompression process may be performed to bond a heat spreader wafer HSW that covers the memory dies M, the mold layer 500, and the conductive posts 300. In this case, a direct bonding process or a hybrid Cu bonding process may be performed. The heat spreader wafer HSW may be disposed so that its passivation layer PV faces down. The heat spreader wafer HSW may be positioned on the fourth memory die M4 to allow the fourth interlayer dielectric layer IL4 of the fourth memory die M4 to contact a third substrate SI3 of the heat spreader wafer HSW, to allow second dummy pads DP2 of the heat spreader wafer HSW to contact the conductive posts 300, and to allow third dummy pads DP3 of the heat spreader wafer HSW to contact the upper chip pads UCP of the fourth memory die M4. Afterwards, a thermocompression process may be performed to directly bond the heat spreader wafer HSW to the memory dies M, the mold layer 500, and the conductive posts 300. The heat spreader wafer HSW and the fourth memory die M4 may be directly bonded through the third dummy pads DP3 and the upper chip pads UCP, and may have an interface formed by their contact with each other. Referring to FIG. 2C, an inorganic dielectric layer such as a silicon oxide layer may be formed between the passivation layer PV of the heat spreader wafer HSW (or a heat spreader HS) and the passivation layer PV of the fourth memory die M4. The heat spreader wafer HSW may have a thickness greater than those of the memory dies M. The difference in thickness may cause that a pressure applied in the thermocompression process for bonding the heat spreader wafer HSW is different from a pressure applied in the thermocompression process for bonding the memory dies M. Thus, as shown in FIG. 2D, the occurrence of voids VOD between the heat spreader wafer HSW and the fourth memory die M4 might be not tightly suppressed and be relatively high.

Referring to FIG. 4G, a grinding or etch-back process may be performed on a top surface of the heat spreader wafer HSW such that a portion of the heat spreader wafer HSW may be removed to reduce a thickness of the heat spreader wafer HSW. The present inventive concepts, however, are not necessarily limited thereto, and it may be possible to omit the procedure of reducing the thickness of the heat spreader wafer HSW. Thereafter, the base die wafer 100W may be separated from the carrier adhesive layer GL.

Referring to FIG. 4H, a dicing process using a laser may be performed to remove the separation region SR, thereby forming a plurality of semiconductor packages 1000. Accordingly, the semiconductor packages 1000 of FIG. 1 may be fabricated.

In a method of fabricating the semiconductor package 1000 according to the present inventive concepts, a wafer bonding method may be used to manufacture the heat spreader HS including the second and third dummy pads DP2 and DP3.

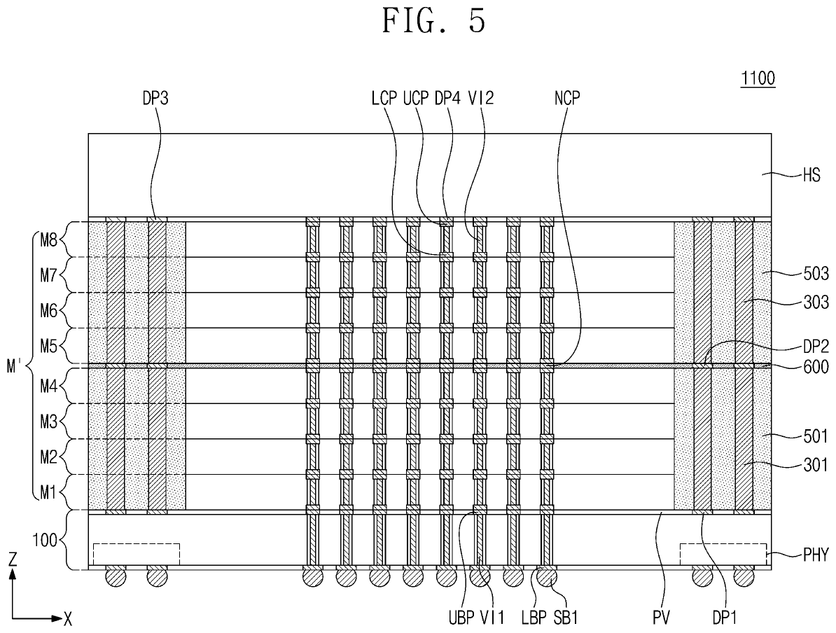

FIG. 5 is a cross-sectional view showing a semiconductor package according to some embodiments of the present inventive concepts.

Referring to FIG. 5, a semiconductor package 1100 may have a structure including the structure shown in FIG. 1 and memory dies M′ stacked in an eight-layered configuration. For example, the memory dies M′ may include first to eighth memory dies M1 to M8. The semiconductor package 1100 may include first conductive posts 301, second conductive posts 303, a first mold layer 501, and a second mold layer 503.

The base die 100 may be provided with first dummy pads DP1 on its edge, in contact with the first conductive posts 301. An interfacial adhesive layer 600 may be interposed between the first conductive posts 301 and the second conductive posts 303, between the first mold layer 501 and the second mold layer 503, and between the fourth memory die M4 and the fifth memory die M5. The interfacial adhesive layer 600 may be a single-layered or multi-layered structure formed of material such as SiCN. Second dummy pads DP2 may be disposed between the first conductive posts 301 and the second conductive posts 303, and the first conductive posts 301 and the second conductive posts 303 may be correspondingly in contact with the second dummy pads DP2. The internal adhesive layer 600 may at least partially surround the second dummy pads DP2. Connection pads NCP may be disposed between upper chip pads UCP of the fourth memory die M4 and lower chip pads LCP of the fifth memory die M5, and the upper chip pads UCP of the fourth memory die M4 and the lower chip pads LCP of the fifth memory die M5 may be in contact with the connection pads NCP. The heat spreader HS may be provided with third dummy pads DP3 on an edge at the bottom surface, in contact with the second conductive posts 303. The heat spreader HS may be provided with fourth dummy pads DP4 on a central portion of the bottom surface, in contact with upper chip pads UCP of the eighth memory die M8. Other configurations may be identical or similar to those discussed with reference to FIGS. 1 to 3.

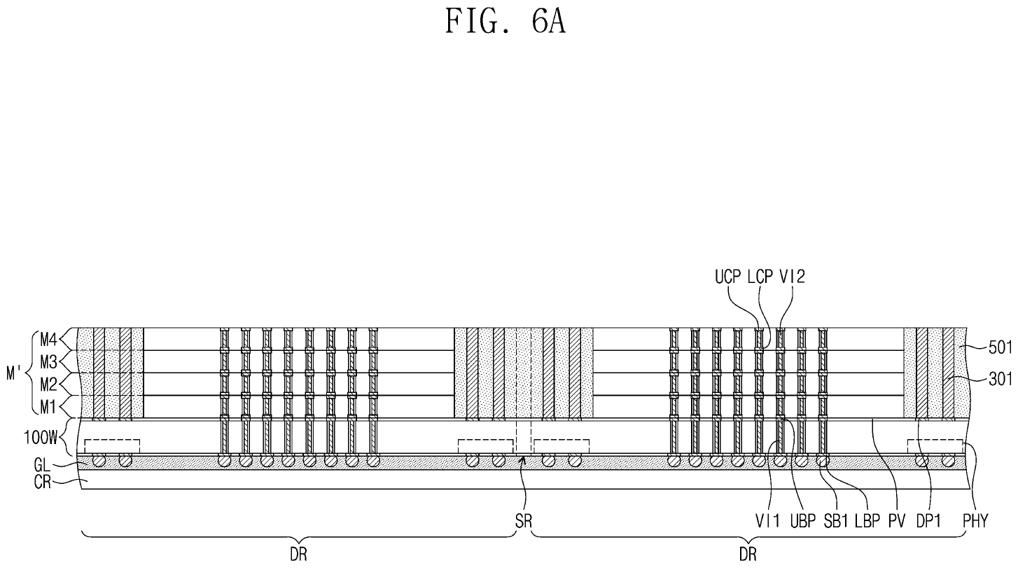

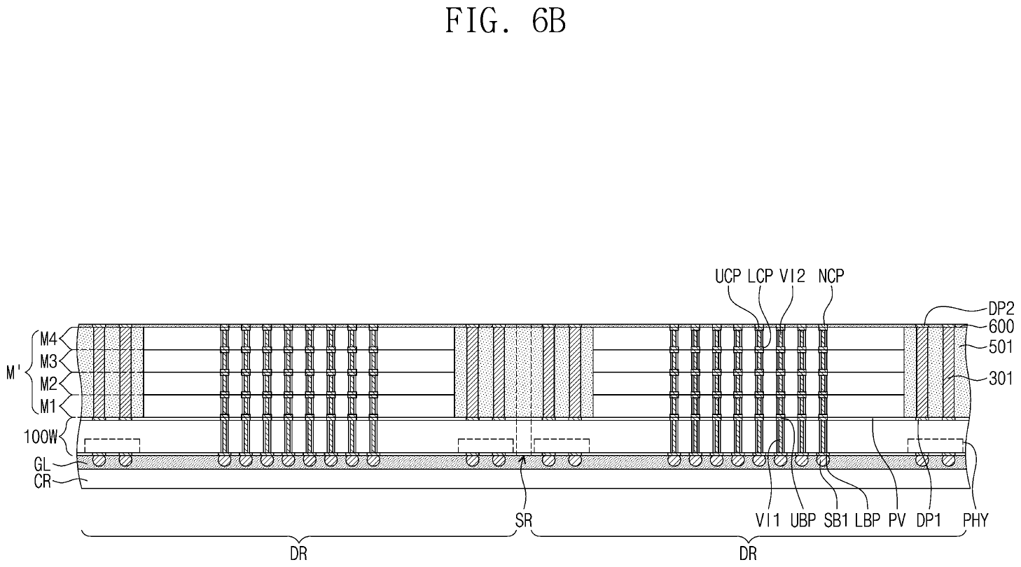

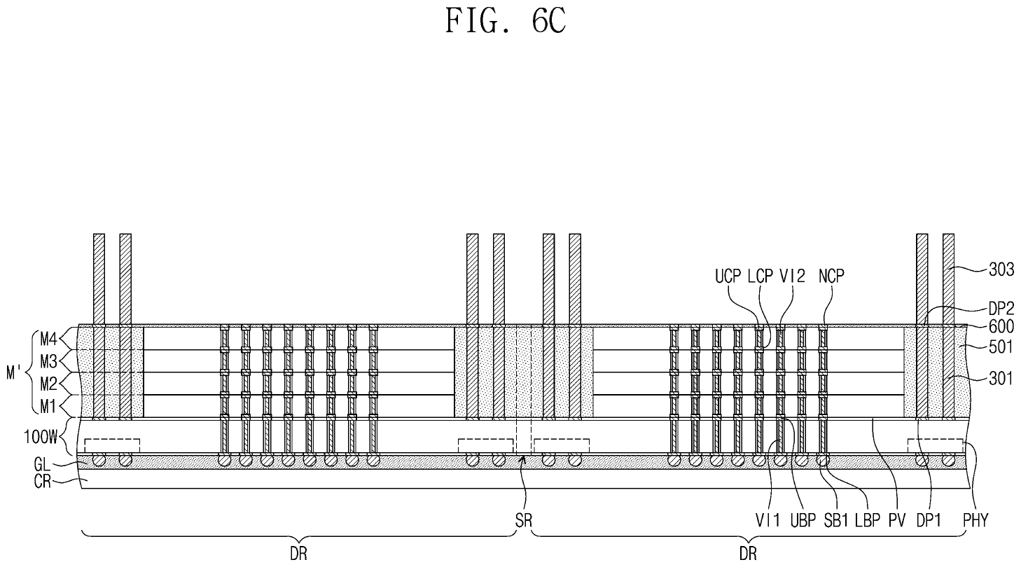

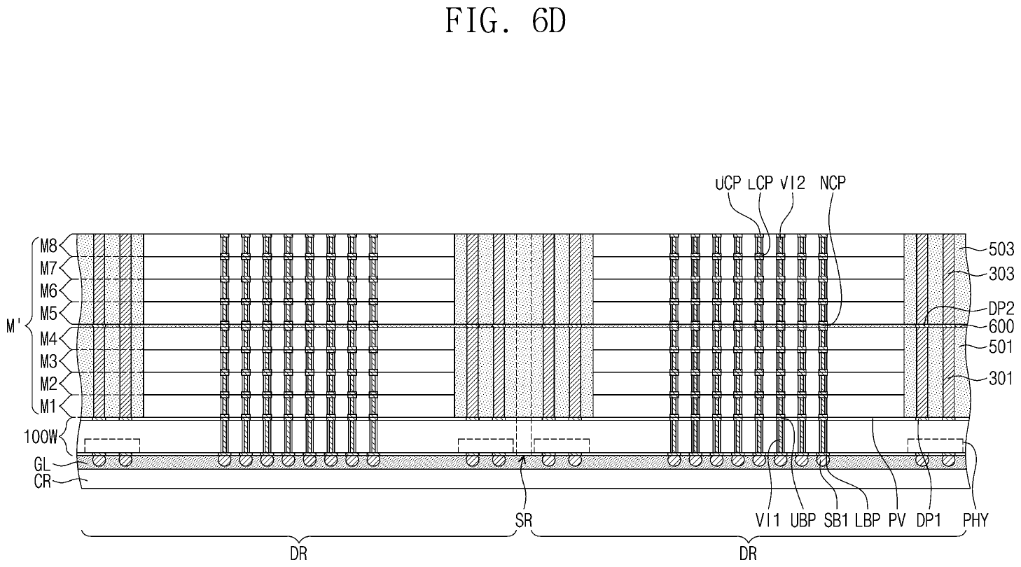

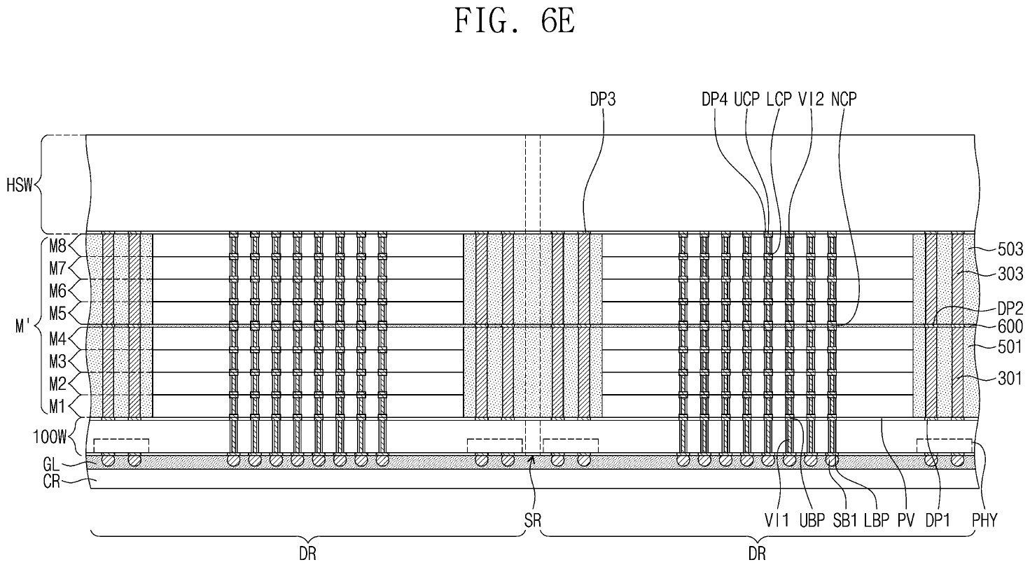

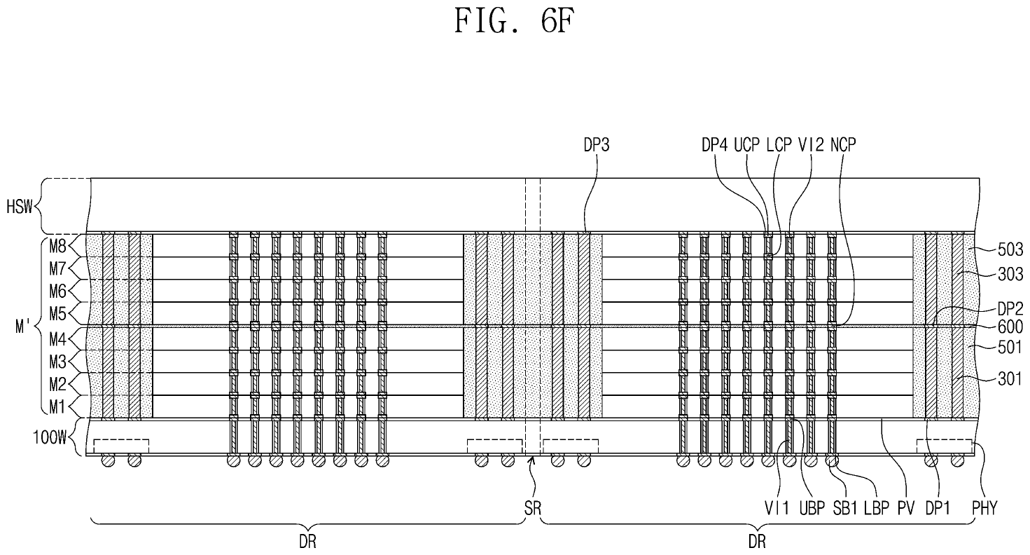

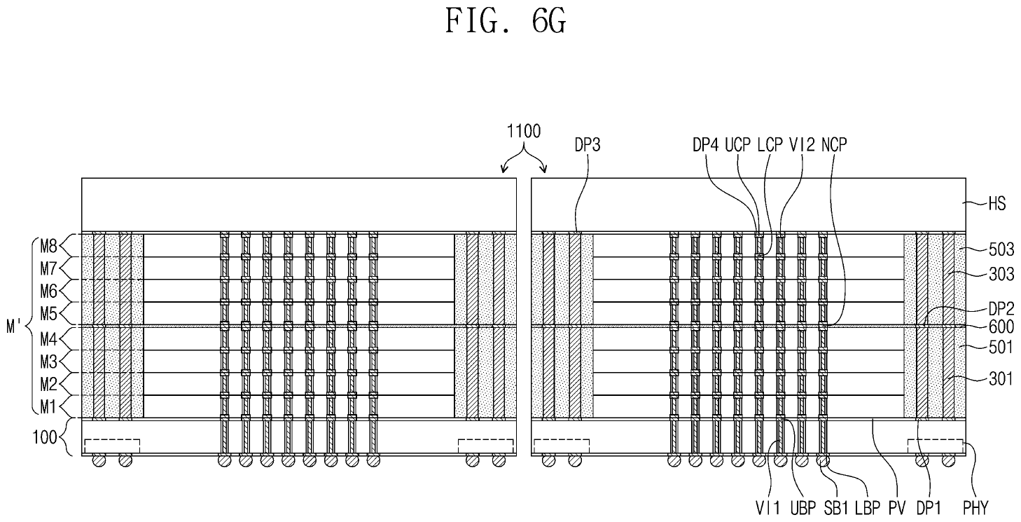

FIGS. 6A to 6G are cross-sectional views showing a method of fabricating the semiconductor package depicted in FIG. 5. The semiconductor package 1100 may be fabricated by the same as or similar method to that discussed in FIGS. 4A to 4H. A duplicate description will be omitted below.

Referring to FIG. 6A, a chemical mechanical polishing (CMP) or etch-back process may be performed to remove at least portions of the first conductive posts 301 and at least a portion of the first mold layer 501, exposing top surfaces of the first conductive posts 301, the fourth memory die M4, the upper chip pads UCP of the fourth memory die M4, and the first mold layer 501.

Referring to FIG. 6B, an interfacial adhesive layer 600 may be conformally formed on the fourth memory die M4, the upper chip pads UCP of the fourth memory die M4, the first mold layer 501, and top surfaces of the first conductive posts 301. Connection pads NCP and second dummy pads DP2 may be formed on the interfacial adhesive layer 600. The connection pads NCP and the second dummy pads DP2 may be formed by performing deposition and etching processes. In some embodiments, a mask pattern may be formed on the interfacial adhesive layer 600, and a plating process may be performed to selectively form connection pads NCP and second dummy pads DP2.

Referring to FIG. 6C, second conductive posts 303 may be formed on an edge of the interfacial adhesive layer 600. The second conductive posts 303 may be correspondingly in contact with the second dummy pads DP2 and may be spaced apart from the connection pads NCP.

Referring to FIG. 6D, fifth to eighth memory dies M5 to M8 may be prepared. Each of the fifth to eighth memory dies M5 to M8 may be provided by performing the same method to form a second through via VI2, upper chip pads UCP, and lower chip pads LCP as discussed in FIG. 4A. Afterwards, a sawing process may be performed to allow the fifth to eighth memory dies M5 to M8 to have the same size. The fifth to eighth memory dies M5 to M8 may be formed to have the same thickness. The fifth to eighth memory dies M5 to M8 may be stacked on the interfacial adhesive layer 600. The lower chip pads LCP of the fifth memory die M5 may be in contact with the connection pads NCP. A thermocompression process may be performed to bond the fifth to eighth memory dies M5 to M8 to the interfacial adhesive layer 600, and then a mold process may be performed to form a second mold layer 503 that covers a top surface of the interfacial adhesive layer 600, lateral surfaces of the fifth to eighth memory dies M5 to M8, and the second conductive posts 303. A chemical mechanical polishing (CMP) or etch-back process may be performed to remove at least portions of the second conductive posts 303 and at least a portion of the second mold layer 503 to expose the eighth memory die M8, the upper chip pads UCP of the eighth memory die M8, the second mold layer 503, and top surfaces of the second conductive posts 303.

Referring to FIG. 6E, a thermocompression process may be performed to bond a heat spreader wafer HSW that covers the memory dies M′, the second mold layer 503, and the second conductive posts 303. In this case, a direct bonding process or a hybrid Cu bonding process may be performed.

Referring to FIG. 6F, a grinding or etch-back process may be performed on a top surface of the heat spreader wafer HSW such that a portion of the heat spreader wafer HSW may be removed to reduce a thickness of the heat spreader wafer HSW. The present inventive concepts, however, are not necessarily limited thereto, and it may be possible to omit the procedure of reducing the thickness of the heat spreader wafer HSW. Thereafter, the base die wafer 100W may be separated from the carrier adhesive layer GL.

Referring to FIG. 6G, a dicing process using a laser may be performed to remove the separation region SR, thereby forming a plurality of semiconductor packages 1100. Accordingly, the semiconductor packages 1100 of FIG. 5 may be fabricated.

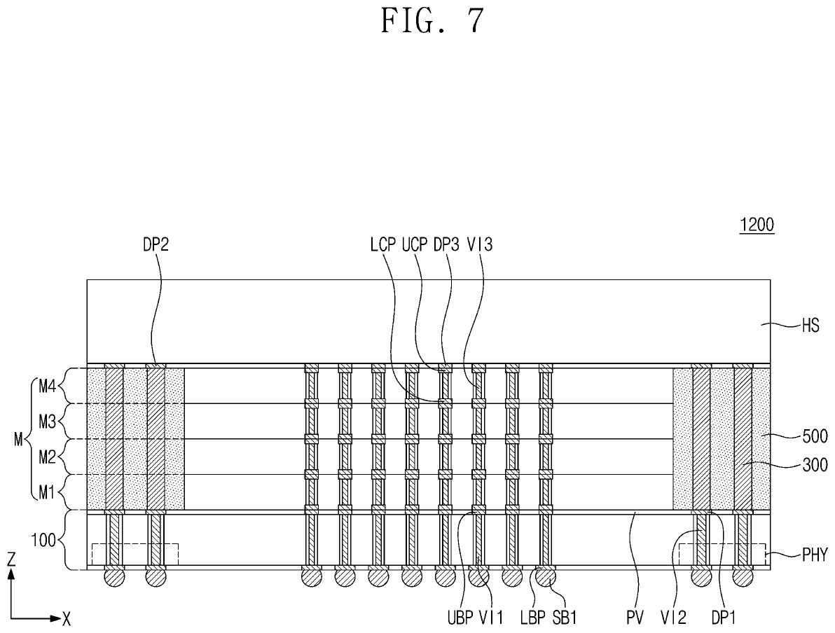

FIG. 7 is a cross-sectional view showing a semiconductor package according to some embodiments of the present inventive concepts.

Referring to FIG. 7, a semiconductor package 1200 may have a structure including the structure shown in FIG. 1 and a base die 100 that includes first and second through vias VI1 and VI2. The base die 100 may include a first substrate (see SI1 of FIG. 2A). The first through via VI1 may vertically penetrate the first substrate SI1 to reside on a central portion of the base die 100, and the second through via VI2 may vertically penetrate the first substrate SI1 to reside on an edge of the base die 100. The second through via VI2 may be connected to the first dummy pads DP1. Each of the first to fourth memory dies M1 to M4 may include a third through via VI3. The second through via VI2 may have a diameter greater than those of the first and third through vias VI1 and VI3. The lower conductive pads LBP may be connected to the first and second through vias VI1 and VI2. Other configurations may be identical or similar to those discussed with reference to FIGS. 1 to 3.

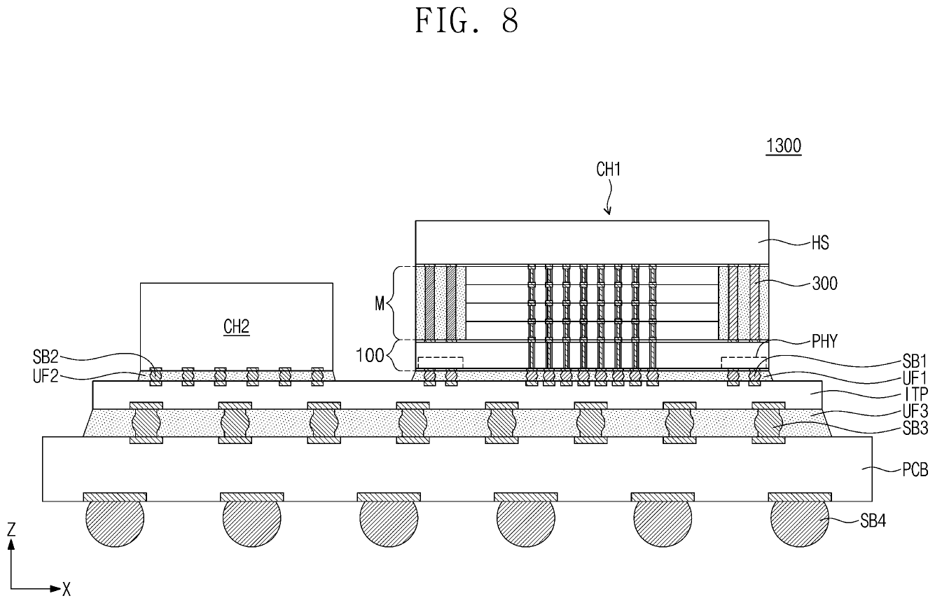

FIG. 8 is a cross-sectional view showing a semiconductor package according to some embodiments of the present inventive concepts.

In a semiconductor package 1300 according to the present embodiment, an interposer substrate ITP may be disposed on a package substrate PCB. The package substrate PCB may be, for example, a double-sided or multi-layered printed circuit board. The interposer substrate ITP may include, for example, silicon. A first semiconductor chip CH1 and a second semiconductor chip CH2 may be disposed side-by-side in the first direction X on the interposer substrate ITP. The interposer substrate ITP may include internal lines that connect the first semiconductor chip CH1 and the second semiconductor chip CH2 to each other. The first semiconductor chip CH1 may be an application specific integrated circuit (ASIC) or a system-on-chip (SOC). The first semiconductor chip CH1 may be called a host or an application processor (AP). The first semiconductor chip CH1 may be connected to the interposer substrate ITP through first external connection members SB1. The second semiconductor chip CH2 may be the same as or similar to the semiconductor package 1000 discussed with reference to FIGS. 1 to 3. The second semiconductor chip CH2 may be connected to the interposer substrate ITP through second external connection members SB2. The interposer substrate ITP may be bonded through to the package substrate PCB third external connection members SB3. Fourth external connection members SB4 may be bonded to a bottom surface of the package substrate PCB. The external connection members SB1 to SB4 may include at least one selected from copper bumps, copper pillars, and/or solder balls. Underfill layers UF1 to UF3 may be provided between the first semiconductor chip CH1 and the interposer substrate ITP, between the second semiconductor chip CH2 and the interposer substrate ITP, and between the interposer substrate ITP and the package substrate PCB. The underfill layers UF1 to UF3 may be formed by dispensing and curing processes. The underfill layers UF1 to UF3 may include an epoxy resin, and may protect the external connection members SB1 to SB3.

In a semiconductor package according to the present inventive concepts, as conductive posts are disposed around memory dies stacked on a base die, and as a heat spreader is disposed to cover the memory dies and the conductive posts, heat of the base die may be effectively dispersed, and thus the semiconductor package may improve reliability and heat dissipation performance.

In a method of fabricating a semiconductor package according to the present inventive concepts, memory dies having the same size may be stacked to easily manage the memory dies, and a heat spreader including dummy pads may be manufactured by wafer bonding to increase a yield.

Although some example embodiments of inventive concepts have been discussed with reference to accompanying figures, it will be understood that various changes in form and details may be made therein without departing from the spirit and scope of inventive concepts. It will be apparent to those skilled in the art that various substitution, modifications, and changes may be thereto without departing from the scope and spirit of the present inventive concepts.

What is claimed is:

1. A semiconductor package, comprising:
a base die that includes first dummy pads on an edge at a top surface of the base die;
a plurality of memory dies on the base die;
a plurality of conductive posts spaced apart from the memory dies and on the edge of the base die;
a mold layer that covers the base die, the memory dies, and the conductive posts; and
a heat spreader that includes second dummy pads on an edge at a bottom surface of the heat spreader and third dummy pads on a central portion of the bottom surface of the heat spreader, wherein the heat spreader is disposed on the memory dies and the mold layer,
wherein the first dummy pads are correspondingly connected to the second dummy pads through the conductive posts, and
wherein the second dummy pads are in contact with the conductive posts.

2. The semiconductor package of claim 1,
wherein the base die includes:
a first substrate;
a first through via that penetrates the first substrate and is disposed on a central portion of the base die; and
a second through via that penetrates the first substrate and is disposed on the edge of the base die,
wherein the memory dies include first, second, third and fourth memory dies that are stacked,
wherein each of the first to fourth memory dies includes:
a second substrate; and
a third through via that penetrates the second substrate and is disposed on a central portion the memory die,
wherein a diameter of the second through via is greater than diameters of the first and third through vias.

3. The semiconductor package of claim 1, wherein
the memory dies include first, second, third and fourth memory dies that are stacked,
the heat spreader and the base die have the same first width,
the first to fourth memory dies have the same second width, and
the first width is greater than the second width.

4. The semiconductor package of claim 1, wherein
the memory dies include first, second, third and fourth memory dies that are stacked,
the first to fourth memory dies have the same first thickness,
the heat spreader has a second thickness, and
the second thickness is greater than the first thickness.

5. The semiconductor package of claim 1, wherein the base die includes:
a first substrate;
a first through via that penetrates the first substrate and is disposed on a central portion of the base die;
a second through via that penetrates the first substrate and is disposed on the edge of the base die;
a plurality of high-power density regions on the first substrate;
a plurality of upper conductive pads on the top surface of the base die and connected to the first through via; and
a lower conductive pad on a bottom surface of the base die and connected to the first and second through vias,
wherein the conductive posts are positioned above the conductive posts, and
wherein the second through via is connected to the first dummy pads.

6. The semiconductor package of claim 5,
wherein the memory dies include first, second, third and fourth memory dies that are stacked,
wherein each of the first to fourth memory dies includes:
a second substrate;
a third through via that penetrates the second substrate and is disposed on a central portion of a corresponding one of the first to fourth memory dies;
a plurality of upper chip pads on a top surface of the corresponding die and connected to the third through via; and
a plurality of lower chip pads on a bottom surface of the corresponding die and connected to the third through via,
wherein the lower chip pads of the first memory die are in contact with the upper conductive pads, and
wherein the lower chip pads of the first memory die and the upper conductive pads are formed of the same material.

7. The semiconductor package of claim 6, wherein
the upper chip pads are in contact with the lower chip pads, and
the upper chip pads and the lower chip pads are formed of the same material.

8. The semiconductor package of claim 6, wherein
the third dummy pads are in contact with the upper chip pads of the fourth memory die, and
the third dummy pads and the upper chip pads of the fourth memory die are formed of the same material.

9. The semiconductor package of claim 6, wherein a size of each of the first and second dummy pads is greater than a size of each of the upper and lower chip pads.

10. The semiconductor package of claim 1, wherein voids are present between an uppermost one of the memory dies and the heat spreader and between the memory dies,
wherein a density of the voids between the uppermost memory die and the heat spreader is greater than a density of the voids between the memory dies.

11. The semiconductor package of claim 1, wherein the conductive posts are spaced apart from each other and surround the memory dies.

12. The semiconductor package of claim 1, wherein the heat spreader includes silicon.

13. A semiconductor package, comprising:
a base die;
a plurality of memory dies on the base die;
a plurality of conductive posts spaced apart from the memory dies and disposed on an edge of the base die;
a mold layer that covers the base die, the memory dies, and the conductive posts; and
a heat spreader on the memory dies and the mold layer,
wherein the base die includes:
a first substrate;
a first through via that penetrates the first substrate and is disposed on a central portion of the base die;
a plurality of upper conductive pads on a top surface of the base die and connected to the first through via;
a plurality of first dummy pads on the edge at the top surface of the base die; and
a plurality of lower conductive pads on a bottom surface of the base die,
wherein the memory dies include first, second, third and fourth memory dies that are stacked,
wherein each of the first to fourth memory dies includes:
a second substrate;
a second through via that penetrates the second substrate and resides on a central portion of the memory die;
a plurality of upper chip pads on a top surface of the memory die and connected to the second through via; and
a plurality of lower chip pads on a bottom surface of the memory die and connected to the second through via,
wherein the heat spreader includes:
a plurality of second dummy pads on an edge at a bottom surface of the heat spreader; and
a plurality of third dummy pads on a central portion of the bottom surface of the heat spreader,
wherein the conductive posts are spaced apart from each other and surround the memory dies,
wherein a diameter of at least one of the conductive posts is greater than a diameter of each of the first and second through vias,
wherein the heat spreader and the base die have the same first width,
wherein the first to fourth memory dies have the same second width,
wherein the first width is greater than the second width, and
wherein the heat spreader includes silicon.

14. The semiconductor package of claim 13, wherein
the first to fourth memory dies have the same first thickness,
the heat spreader has a second thickness, and
the second thickness is greater than the first thickness.

15. The semiconductor package of claim 13, wherein the base die further includes high-power density regions,
wherein the conductive posts are positioned above the high-power density regions.

16. The semiconductor package of claim 13, wherein
the lower chip pads of the first memory die are in contact with the upper conductive pads, and
the lower chip pads of the first memory die and the upper conductive pads are formed of the same material.

17. The semiconductor package of claim 13, wherein
the third dummy pads are in contact with the upper chip pads of the fourth memory die, and
the third dummy pads and the upper chip pads of the fourth memory die are formed of the same material.

18. The semiconductor package of claim 13, wherein the conductive posts are in contact with the first and second dummy pads.

19. The semiconductor package of claim 13, wherein a size of each of the first and second dummy pads is greater than a size of each of the upper and lower chip pads.

20. A semiconductor package, comprising:
a package substrate;
an interposer substrate on the package substrate;
a first semiconductor chip on the interposer substrate; and
a second semiconductor chip on the interposer substrate,
wherein the second semiconductor chip includes:
a base die that includes first dummy pads on an edge at a top surface of the base die;
a plurality of memory dies on the base die;
a plurality of conductive posts spaced apart from the memory dies and on the edge of the base die;
a mold layer that covers the base die, the memory dies, and the conductive posts; and
a dummy die that includes second dummy pads on an edge at a bottom surface of the dummy die and third dummy pads on a central portion of the bottom surface of the dummy die, the dummy die being disposed on the memory dies and the mold layer, and
wherein the dummy die and the base die have the same first width.
